(19) United States
(12) Patent Application Publication
(10) Pub. No.: US 2026/0096256 A1
(43) Pub. Date: Apr. 2, 2026

(54) LENS STRUCTURES IN MULTIPLE-CHIP LIGHT-EMITTING DIODE (LED) PACKAGES

(71) Applicant: CreeLED, Inc., Durham, NC (US)

(72) Inventors: Andre Pertuit, Raleigh, NC (US); Michael Check, Holly Springs, NC (US); Colin Blakely, Raleigh, NC (US); David Suich, Durham, NC (US); Joseph G. Sokol, Durham, NC (US); Robert Wilcox, Rolesville, NC (US); F James Claire, Chapel Hill, NC (US)

(21) Appl. No.: 18/901,734

(22) Filed: Sep. 30, 2024

(51) Int. Cl. H01L 33/58; H01L 25/075; H01L 33/50; H01L 33/54

(52) U.S. Cl. CPC H10H 20/855; H10H 20/8515; H10H 20/853; H10W 90/00

(57) ABSTRACT

Light-emitting diode (LED) devices and more particularly lens structures in multiple-chip LED packages are disclosed. Lens structures include separate lenses positioned to reduce optical decoupling from corresponding LED chips. Individual lenses for each individual LED chip provide flexibility in tailoring each lens to provide a portion of aggregate emissions with a targeted profile. Multiple lenses may be integrally formed from a common encapsulant material. Other lens structures include separate lenses provided on or through encapsulant materials. Combinations of different LED chip structures and different lens structures within a common LED package are disclosed.

### FIELD OF THE DISCLOSURE

The present disclosure relates to light-emitting diode (LED) devices, and more particularly to lens structures in multiple-chip LED packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays and lighting devices for general illumination.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that can provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to lens structures in multiple-chip LED packages. Lens structures include separate lenses positioned to reduce optical decoupling from corresponding LED chips. Individual lenses for each individual LED chip provide flexibility in tailoring each lens to provide a portion of aggregate emissions with a targeted profile. Multiple lenses may be integrally formed from a common encapsulant material. Other lens structures include separate lenses provided on or through encapsulant materials. Combinations of different LED chip structures and different lens structures within a common LED package are disclosed.

In one aspect, an LED package comprises: a submount; a plurality of LED chips on the submount; and an encapsulant on the plurality of LED chips and the submount, the encapsulant forming a plurality of lenses on the plurality of LED chips and a lateral extension integrally connecting each lens of the plurality of lenses, the lateral extension further extending to a perimeter edge of the submount.

In certain embodiments, the plurality of LED chips comprises a first LED chip and a second LED chip, wherein lateral edges of the first LED chip are nonparallel with any perimeter edge of the submount, and lateral edges of the second LED chip are parallel with at least one perimeter edge of the submount. In certain embodiments, the plurality of LED chips comprises a first LED chip and a second LED chip, and wherein the plurality of lenses comprises a first lens on the first LED chip and a second lens on the second LED chip. In certain embodiments, the first LED chip comprises a lumiphoric material such that a portion of light from the first LED chip is subject to wavelength conversion, and wherein the second LED chip is devoid of lumiphoric material. In certain embodiments, the first LED chip comprises a vertical chip structure with a contact structure on a light-emitting surface of the first LED chip, and the second LED chip comprises a flip-chip structure. In certain embodiments, the plurality of lenses comprises a first lens on the first LED chip and a second lens on the second LED chip, wherein the first lens and the second lens have different shapes from one another relative to the submount.

In certain embodiments: the first lens comprises a first curved surface with a first planar side surface; and the second lens comprises a second curved surface with a second planar side surface. In certain embodiments, the first planar side surface and the second planar side surface are positioned away from one another relative to a center point of the submount. In certain embodiments, the first planar side surface and the second planar side surface are both positioned toward a center point of the submount. In certain embodiments, a lateral edge of the first LED chip is parallel with the first planar side surface, and a lateral edge of the second LED chip is parallel with the second planar side surface. In certain embodiments: the plurality of LED chips comprises a third LED chip and a fourth LED chip; the plurality of lenses comprises a third lens on the third LED chip and a fourth lens on the fourth LED chip; the third lens comprises a third curved surface with a third planar side surface; the fourth lens comprises a fourth curved surface with a fourth planar side surface; the first planar side surface and the fourth planar side surface face away from a center point of the submount; and the second planar side surface and the third planar side surface face toward the center point of the submount. In certain embodiments, the first lens comprises a thickness that is greater than a thickness of the second lens. In certain embodiments, the first lens forms a bullet shape and the second lens forms a dome shape. In certain embodiments, the first lens comprises a curved lens and the second lens comprises a flat lens.

In certain embodiments: the plurality of LED chips comprises a first LED chip and a second LED chip; and the plurality of lenses comprises a first lens on the first LED chip, a second lens on the second LED chip, and a third lens on both the first lens and the second lens.

In another aspect, an LED package comprises: a submount; a first LED chip and a second LED chip of the submount; an encapsulant forming a first lens on the first LED chip, a second lens on the second LED chip, and a lateral extension integrally connecting the first lens and the second lens; and a third lens on the encapsulant, the third lens covering the first lens, the second lens, and portions of the lateral extension. In certain embodiments: the first lens comprises a first curved surface with a first planar side surface; and the second lens comprises a second curved surface with a second planar side surface. In certain embodiments, the first planar side surface and the second planar side surface are positioned away from one another on the submount. In certain embodiments, the first planar side surface and the second planar side surface are both positioned toward each other on the submount. In certain embodiments, the third lens comprises an index of refraction that is different than the encapsulant. In certain embodiments, the third lens comprises light-scattering particles dispersed in a binder.

In another aspect, an LED package comprises: a submount; a first LED chip and a second LED chip of the submount; an encapsulant covering the first LED chip and the second LED chip, the encapsulant forming a planar top surface above the first LED chip and the second LED chip; and a first lens with a curved surface above the planar top surface in a position that is vertically registered with the first LED chip. The LED package may further comprise a second lens on the planar top surface in a position that is vertically registered with the second LED chip. In certain embodiments, the first lens is on the planar top surface. In certain embodiments, the first lens extends through the encapsulant such that the planar top surface terminates at a portion of the first lens that is above the first LED chip.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top view of a light-emitting diode (LED) package with multiple LED chips and corresponding lenses according to aspects of the present disclosure.

FIG. 1B is a cross-sectional view of the LED package of FIG. 1A taken along the cross-sectional line 1B-1B of FIG. 1A.

FIG. 2 is a top view of an LED package that is similar to the LED package of FIG. 1A with a different layout of LED chips and corresponding lenses.

FIG. 3 is a top view of an LED package that is similar to the LED package of FIG. 1A with LED chips that provide different combinations of light output.

FIG. 4 is a top view of an LED package that is similar to the LED package of FIG. 3 with LED chips that provide different LED chip structures and/or combinations of light output.

FIG. 5 is a top view of an LED package that is similar to the LED package of FIG. 1A for embodiments where shapes of lenses vary across the submount.

FIG. 6 is a top view of an LED package that is similar to the LED package of FIG. 5 for an alternative arrangement of the lenses.

FIG. 7 is a top view of an LED package that is similar to the LED package of FIG. 3 for embodiments with a different configuration of the lumiphoric material.

FIG. 8A is a top view of an LED package similar to the LED package of FIGS. 1A and 1B for embodiments with an alternative arrangement of lenses.

FIG. 8B is a cross-sectional view of the LED package of FIG. 8A taken along the cross-sectional line 8B-8B of FIG. 8A.

FIG. 9A is a top view of an LED package similar to the LED package of FIG. 6 for compound lens embodiments where another lens is formed to cover each individual lens.

FIG. 9B is a cross-sectional view of the LED package of FIG. 9A taken along the cross-sectional line 9B-9B of FIG. 9A.

FIG. 10A is a top view of an LED package similar to the LED package of FIG. 1A for an alternative embodiment of the encapsulant.

FIG. 10B is a cross-sectional view of the LED package of FIG. 10A taken along the cross-sectional line 10B-10B of FIG. 10A.

FIG. 11A is a top view of an LED package similar to the LED package of FIG. 1A for an alternative embodiment of the encapsulant and lenses.

FIG. 11B is a cross-sectional view of the LED package of FIG. 11A taken along the cross-sectional line 11B-11B of FIG. 11A.

FIG. 12 is a cross-sectional view of an LED package similar to the LED package of FIGS. 10A and 10B for an alternative embodiment of the encapsulant and lenses.

FIG. 13 is a cross-sectional view of an LED package similar to the LED package of FIG. 12 for an alternative arrangement of the encapsulant and lenses.

FIG. 14 is a top view of an LED package similar to the LED package of FIG. 5 for embodiments with an alternative layout of the lenses and corresponding planar side surfaces.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to lens structures in multiple-chip LED packages. Lens structures include separate lenses positioned to reduce optical decoupling from corresponding LED chips. Individual lenses for each individual LED chip provide flexibility in tailoring each lens to provide a portion of aggregate emissions with a targeted profile. Multiple lenses may be integrally formed from a common encapsulant material. Other lens structures include separate lenses provided on or through encapsulant materials. Combinations of different LED chip structures and different lens structures within a common LED package are disclosed.

Before delving into specific details for aspects of the present disclosure, an overview of various elements that may be included in exemplary LED packages is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer may comprise a single quantum well, a multiple quantum well, a double heterostructure, and/or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure may emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum (e.g., 100 nm to 400 nm), or one or more portions of the near infrared spectrum, and/or the infrared spectrum (e.g., 700 nm to 1000 nm).

Aspects of the present disclosure are applicable to multiple-chip LED packages where multiple LED chips are arranged on a common submount. In certain embodiments, LED packages may include red, green, and blue LED chips such that the LED package may be positioned as a pixel in an LED display. In certain embodiments, multiple LED chips within a single LED package may be configured to generate a same emission wavelength and/or color. In further embodiments, aspects of the present disclosure may be applicable to other LED packages, such as those that include one or more LED chips with a recipient lumiphoric material that converts at least a portion of light generated from the one or more LED chips to a different wavelength.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG: Ce), green (e.g., LuAg:Ce), and red (e.g., Cai-x-ySrxEuyAlSiN3) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a lead frame structure or a submount.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Light-altering materials may be arranged within LED packages to reflect or otherwise redirect light from the one or more LED chips in a desired emission direction or pattern. Encapsulant materials, such as silicone, epoxy, or polymethyl methacrylate (PMMA), among others, may be formed to encapsulate the LED chips over a submount. In certain embodiments, one or more lumiphoric materials, such as phosphor particles, may be integrated or otherwise embedded within the encapsulant material.

Moreover, encapsulant materials may be shaped to form single lens structures and/or multiple lens structures in a single LED package.

Light-altering materials may be arranged within LED packages, such as along submount surfaces, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO2), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

Certain LED applications benefit from multi-chip packages for light output and/or efficiency reasons. However, LED packages with multiple LED chips under a single lens may exhibit optical issues. Since most LED chips under a single lens cannot be centered with respect to a shape of the single lens, associated optical decoupling contributes to optical losses. Additionally, less flexibility is present regarding spacings between LED chips under a single lens since increased spacing increases optical decoupling to the single lens and decreased spacing may contribute to unintended cross-talk in LED chip emissions. By way of example, in horticultural applications, it is desirable for light output to be spread evenly across large viewing angles. A multiple LED chip package with a single lens for this application may not achieve the desired viewing angles since light output may be concentrated. In this manner, it is common to employ multiple single-chip LED packages together.

According to aspects of the present disclosure, light output for various targeted emission angles may be achieved with lens structures in LED packages having multiple LED chips. Multiple-chip LED packages of the present disclosure are capable of delivering greater amounts of light and with greater efficiency. Exemplary LED packages include individual lenses for LED chips with structures that provide a macro-optical system for effectively spreading light across larger viewing angles. In this regard, LED packages of the present disclosure allow for the benefit of a multi-chip component with increased light output while addressing concerns associated with effective spreading of light.

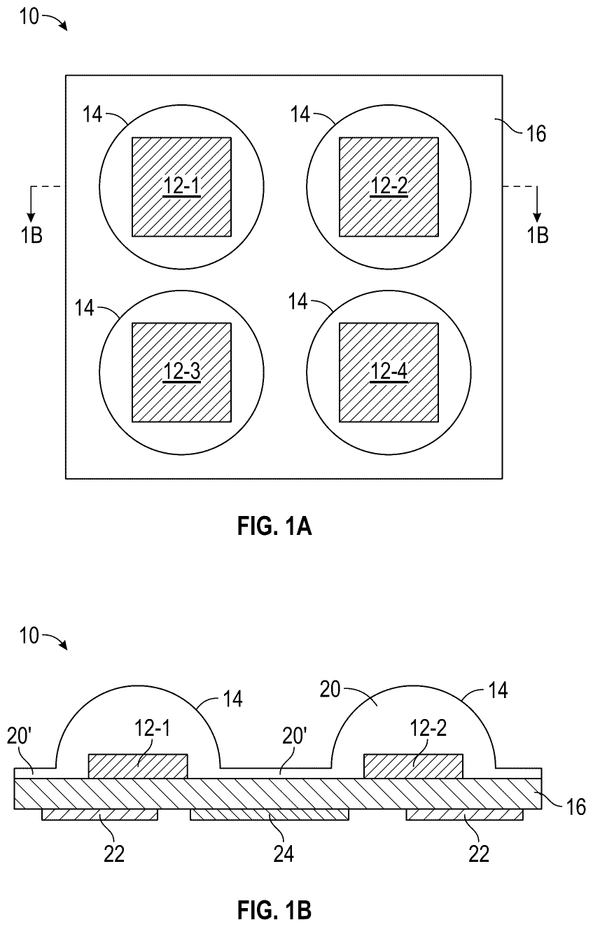

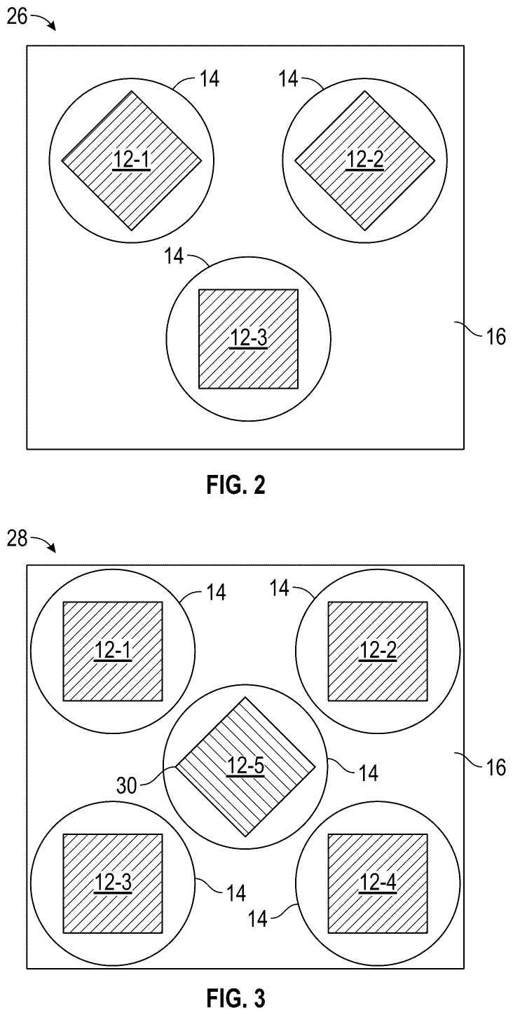

FIG. 1A is a top view of an LED package 10 with multiple LED chips 12-1 to 12-4 and corresponding lenses 14 according to aspects of the present disclosure. FIG. 1B is a cross-sectional view of the LED package 10 of FIG. 1A taken along the cross-sectional line 1B-1B of FIG. 1A. The LED chips 12-1 to 12-4 are positioned in an array across a submount 16 and each individual LED chip 12-1 to 12-4 is positioned to primarily emit light into a corresponding lens 14. In this manner, each single LED chip 12-1 to 12-4 is vertically registered with a corresponding single lens 14 to form an array of LED chips 12-1 to 12-4 and corresponding lenses 14. By positioning each single LED chip 12 between the submount 16 and a corresponding single lens 14, optical coupling may be improved while also allowing suitable spacing to reduce unintended cross-talk between LED chips 12-1 to 12-4. Moreover, shapes of individual lenses 14 may be independently selected for emission profiles of individual chips 12-1 to 12-4, thereby allowing different shapes in the same LED package 10 in certain embodiments. By way of example, each lens 14 is illustrated with a dome or semi-hemispherical shape, however each lens 14 may comprise many different shapes depending on the desired shape of the light output. Suitable shapes include hemispheric, ellipsoid, ellipsoid bullet, cubic, flat, hex-shaped, square, shapes with curved and planar surfaces, such as a hemispheric or curved top portion with planar side surfaces, and various combinations thereof in the same LED package 10. In embodiments where each LED chip 12-1 to 12-4 is configured to emit a same wavelength or color (e.g., all red LED chips, or all blue LED chips, or all green LED chips, or all white LED chips) the shape of each lens 14 may be the same for certain emission profiles or different to provide other emission profiles. In further embodiments, different ones of the LED chips may be configured to emit different wavelengths and/or colors (e.g., red, blue, green, and/or white) and shapes of lenses 14 may be varied across the submount 16. While four LED chips 12-1 to 12-4 are illustrated in FIG. 1, the principles described are applicable to any number of multiple LED chips forming an array within the LED package 10.

In certain embodiments, each lens 14 may be formed as a unitary part of an encapsulant 20 that is provided to cover each LED chip 12-1 to 12-4. For example, the encapsulant 20 may form a continuous structure with an extension 20′, such as a flash portion, that forms a generally flat surface integrally connecting each lens 14. Moreover, the extension 20′ may extend to cover surfaces of the submount 16 outside the array formed by the LED chips 12-1 to 12-4 all the way to one or more perimeter edges of the submount 16.

Accordingly, the encapsulant 20 may form multiple lenses 14 for light shaping while also providing improved environmental protection for underlying portions of both the LED chips 12-1 to 12-4 and the submount 16. As illustrated, a thickness of the extension 20′ of the encapsulant 20 may be substantially thinner than a height of each lens 14. The encapsulant 20 may comprise various materials, such as silicone, epoxy, PMMA glass, and the like.

For embodiments where the LED package 10 is a surface mount device, package contact pads 22 are provided on a bottom surface of the submount 16, opposite the LED chips 12-1 to 12-4. In certain embodiments, the LED package 10 may include two package contact pads 22 that form an anode contact pad and a cathode contact pad for the entire LED package 10. In other embodiments, the LED package 10 may include additional pairs of package contact pads 22 for each LED chip 12-1 to 12-4, thereby providing individual control for each LED chip 12-1 to 12-4. In certain embodiments, the LED package 10 may also include a thermal pad 24 on the bottom of the submount 16 that is positioned to effectively draw heat away from the LED chips 12-1 to 12-4 during operation. The thermal pad 24 may be omitted in other applications. In certain embodiments, the package contact pads 22 and the thermal pad 24 may be patterned together with a same material, such as a metal or metal alloy.

FIG. 2 is a top view of an LED package 26 that is similar to the LED package 10 of FIG. 1 with a different layout of LED chips 12-1 to 12-3 and corresponding lenses 14. In FIG. 2, two LED chips 12-1, 12-2 are rotated on the submount 16 such that lateral edges of the LED chips 12-1, 12-2 are misaligned or nonparallel with perimeter edges of the submount 16. By rotating the LED chips 12-1, 12-2, localized emission profiles associated with each LED chip 12-1, 12-2 and each corresponding lens 14 may also be rotated without changing a shape of each lens 14. In other embodiments, the shapes of each lens 14 may also be changed relative to one another to provide different emission profiles. In certain embodiments, another LED chip 12-3 within the LED package 26 may not be rotated such that lateral edges of the LED chip 12-3 are aligned and/or parallel with corresponding perimeter edges of the submount 16. In this manner, a combined emission profile for the LED package 26 includes aggregate emissions from localized emission profiles associated with each LED chips 12-1 to 12-3 and corresponding lens 14.

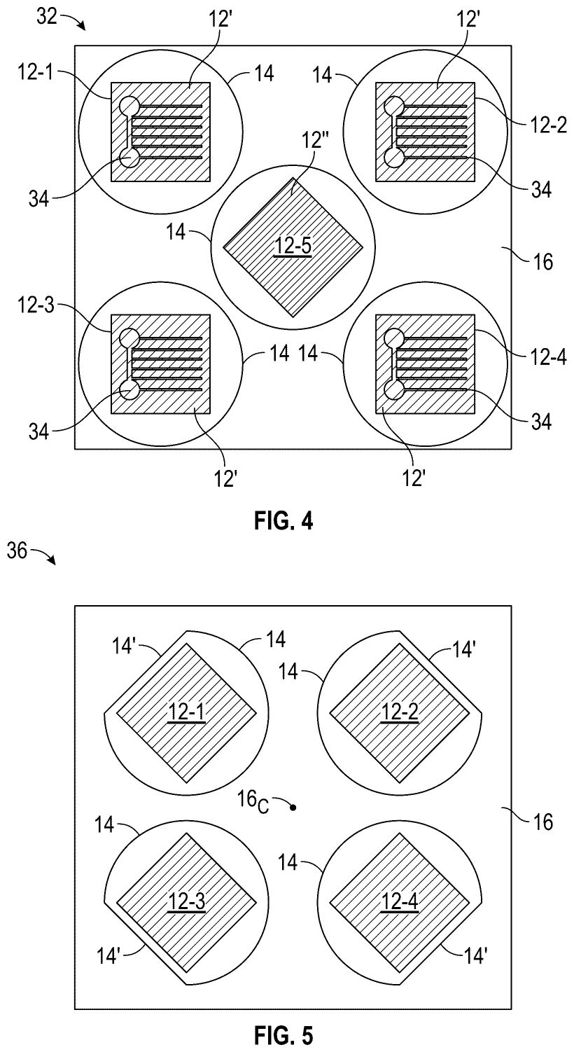

FIG. 3 is a top view of an LED package 28 that is similar to the LED package 10 of FIG. 1 with LED chips 12-1 to 12-5 that provide different combinations of light output. For example, the LED chips 12-1 to 12-4 may embody LED chips that emit light at a same particular wavelength range, such as blue light, green light, or red light, as determined by the active LED structure of the LED chips 12-1 to 12-4. The LED chip 12-5 may be configured to provide a different wavelength range and/or color than the LED chips 12-1 to 12-4. In certain embodiments, the LED chip 12-5 emits light of a different wavelength as determined by the active LED structure of the LED chip 12-5. For example, the LED chips 12-1 to 12-4 may be configured to emit red light while the LED chip 12-5 may be configured to emit blue or green light. In still further embodiments, the LED chip 12-5 may include a lumiphoric material 30 such that at least a portion of light is subject to wavelength conversion, thereby providing a broader range of wavelengths than the LED chips 12-1 to 12-4 that are devoid of lumiphoric material. In the example of FIG. 3, the lumiphoric material 30 may be provided on a top surface of the LED chip 12-5 as a chip-level coating or a wavelength conversion structure that is attached to the LED chip 12-5. The wavelength conversion structure may embody a layer of phosphor deposited on a transparent support element such as glass, a phosphor-in-glass structure, a ceramic phosphor plate, or a single crystal phosphor.

In each of the above examples, the LED chip 12-5 may provide a different emission profile than the LED chips 12-1 to 12-4. By providing separate lenses 14, each LED chip 12-1 to 12-5 may be positioned with respect to a corresponding lens 14 with reduced optical loss. In certain embodiments, the shape of the lens 14 for the LED chip 12-5 may be different than shapes of lenses 14 for the LED chips 12-1 to 12-4 to account for emission profile differences. As further illustrated in FIG. 3, the LED chip 12-5 may be centrally positioned on the submount 16 and rotated such that lateral edges of the LED chip 12-5 are nonparallel with perimeter edges of the submount 16. The other four LED chips 12-1 to 12-4 may have edges that are parallel with at least one perimeter edge of the submount 16. Accordingly, the rotation of the LED chip 12-5 may be set to provide aggregate emissions in combination with the LED chips 12-1 to 12-4 that are targeted to a particular aggregate emission profile.

FIG. 4 is a top view of an LED package 32 that is similar to the LED package 28 of FIG. 3 with LED chips 12-1 to 12-5 that provide different LED chip structures and/or combinations of light output. For example, the LED chips 12-1 to 12-4 may embody vertical LED chips while the LED chip 12-5 embodies a flip-chip structure. The vertical structure for the LED chips 12-1 to 12-4 provides a contact structure 34 on top surfaces thereof that also form light-emitting surfaces 12′. The contact structure 34 for each LED chips 12-1 to 12-4 may include a single contact pad, multiple interconnected contact pads, and/or current spreading fingers. As illustrated, the contact structure 34 is positioned in the light path on the light-emitting surfaces 12′ for emissions from the LED chips 12-1 to 12-4. Moreover, the active LED structure may be closer to the contact structure 34 near the top of each LED chip 12-1 to 12-4. In contrast, the flip-chip structure for the LED chip 12-5 positions a top surface of the LED chip 12-5 as a light-emitting surface 12″ that is generally devoid of contact structures 34, and the light-emitting surface 12″ of the LED chip 12-5 may embody a surface of a thicker growth substrate that positions the active LED structure for the LED chip 12-5 farther away from its light-emitting surface 12″. Accordingly, an emission profile for the LED chip 12-5 may be different than emission profiles for the LED chips 12-1 to 12-4. As with other embodiments, having separate lenses 14 for each LED chip 12-1 to 12-5 provides the ability to tailor each emission profile independently to provide a targeted aggregate emission profile.

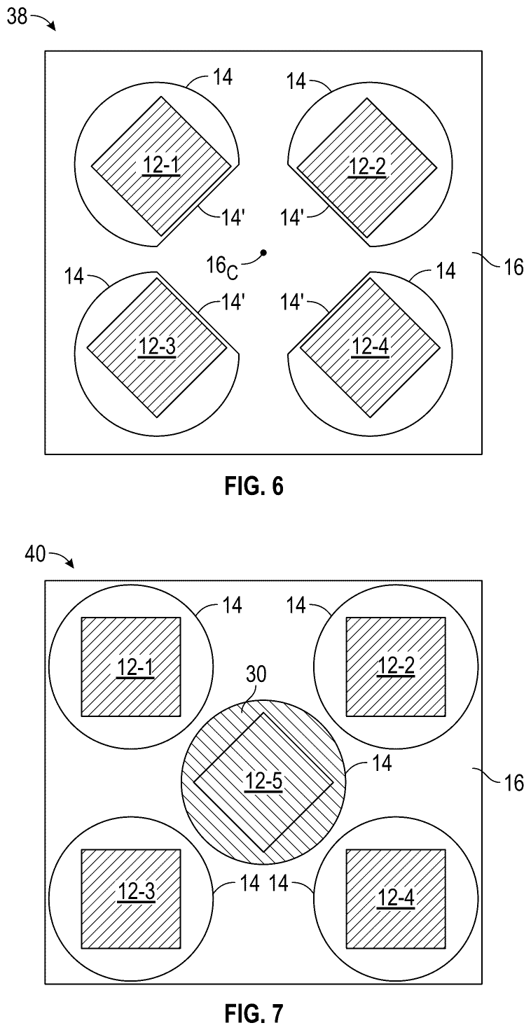

FIG. 5 is a top view of an LED package 36 that is similar to the LED package 10 of FIG. 1A for embodiments where shapes of lenses 14 vary across the submount 16. The shape of each lens 14 may be varied based on structural variations between each underlying LED chip 12-1 to 12-4 as described above for FIGS. 3 and 4. In certain embodiments, the shape of each lens 14 may also be varied based on the spatial position of each lens 14 on the submount 16, alone or in combination with any structural differences in the LED chips 12-1 to 12-4. In this regard, different shapes for each lens 14 are configured to collectively achieve a desired aggregate emission profile for the LED package 36. By way of example, each lens 14 generally has a curved surface, such as a dome shape, but with a planar side surface 14′. The planar side surface 14′ may increase amounts of recipient light subject to total internal reflection (TIR) at the planar side surface 14′, thereby redirecting such light to other portions of the curved surface with increased probability of escaping each lens 14. In certain embodiments, the planar side surface 14′ for each LED chip is positioned in a different direction away from a center point 16C of the top surface of the submount 16. Such an arrangement may effectively redirect increased amounts of light toward the center such that aggregate emissions from each LED chip 12-1 to 12-14 and lens 14 are more columnated for a narrow emission beam of the LED package 36. In certain embodiments, the planar side surface 14′ of each lens 14 may be aligned and/or parallel with a lateral edge of a corresponding LED chip 12-1 to 12-4 to further tailor amounts of light subject to TIR at each planar side surface 14′. In the example of FIG. 6, the planar side surface 14′ of each lens 14 is positioned in a direction toward a corresponding corner of the submount 16 to further collimate aggregate emissions exiting the LED package 36.

FIG. 6 is a top view of an LED package 38 that is similar to the LED package 36 of FIG. 5 for an alternative arrangement of the lenses 14. In FIG. 6, each planar side surface 14′ is positioned in a direction toward the center point 16C of the top surface of the submount 16 instead of away from it as illustrated in FIG. 5. In the arrangement of FIG. 6, the planar side surfaces 14′ may effectively increase amounts of light subject to TIR propagating toward the center point 16C, thereby redirecting such light toward the other curved surfaces of each lens 14. Accordingly, aggregate emissions for the LED package 38 may have a wider overall emission profile.

FIG. 7 is a top view of an LED package 40 that is similar to the LED package 28 of FIG. 3 for embodiments with a different configuration of the lumiphoric material 30. In FIG. 7, the lumiphoric material 30 is positioned on the LED chip 12-5 and on portions of the submount 16 adjacent to the LED chip 12-5. In certain embodiments, the lumiphoric material 30 may extend to edges of the lens 14 without extending past the lens 14. The lumiphoric material 30 may embody a spray coated material that is applied through a patterned mask, or a dispensed material on the LED chip 12-5, or the lumiphoric material 30 may be dispersed as an integral component of the lens 14.

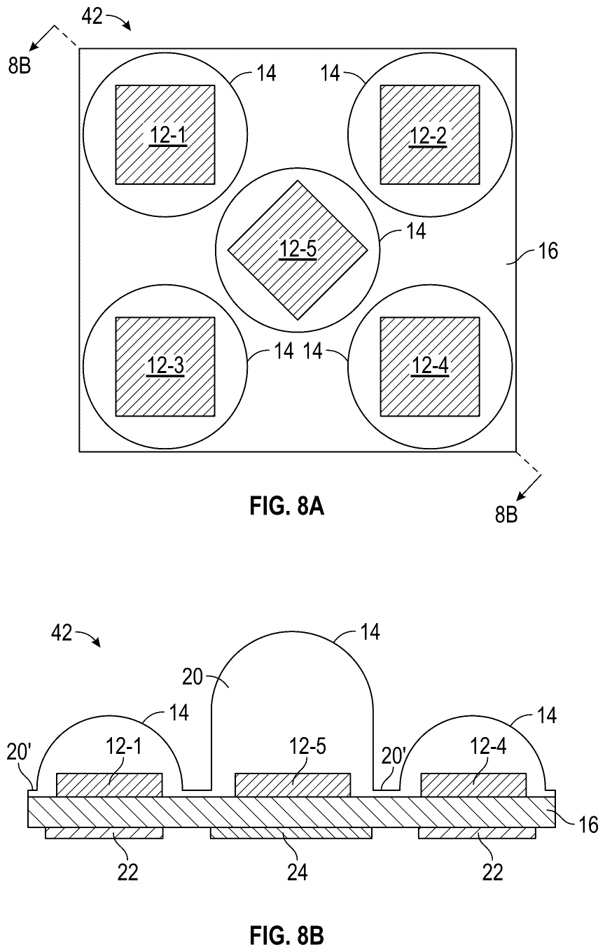

FIG. 8A is a top view of an LED package 42 similar to the LED package 10 of FIGS. 1A and 1B for embodiments with an alternative arrangement of lenses 14. FIG. 8B is a cross-sectional view of the LED package 42 of FIG. 8A taken along the cross-sectional line 8B-8B of FIG. 8A. As illustrated, the lens 14 over the LED chip 12-5 has a height that is greater than a height of the other lenses 14 over the other LED chips 12-1 and 12-4. While not shown in the cross-sectional view of FIG. 1B, the lenses 14 for the LED chips 12-2 and 12-3 may have a similar shape as the lenses 14 for the LED chips 12-1 and 12-4. By way of example, the LED chip 12-5 is centrally positioned with respect to the submount 16 with the other LED chips 12-1 to 12-4 positioned laterally around the LED chip 12-5. The lens 14 for the LED chip 12-5 may have an elongated shape, such as a bullet shape, that provides a narrower emission pattern for light from the LED chip 12-5, while the other LED chips 12-1 to 12-4 have lenses with a general dome shape that provides a broader emission pattern. In this regard, aggregate emissions for the LED package 42 may be composed of a narrow emission pattern that is centrally located and laterally surrounded by an array of broader emission patterns.

In certain embodiments, the LED chip 12-5 may be separately addressable relative to the LED chips 12-1 to 12-4. Accordingly, the LED chip 12-5 may be electrically activated while the other LED chips 12-1 to 12-4 are inactive to provide a narrow emission pattern for the LED package 42. When electrically activated, the LED chips 12-1 to 12-4 may provide a broader emission pattern, thereby providing the capability for the LED package 42 to be selectively switched between different emission patterns. Moreover, the LED chip 12-5 may be configured to provide a similar luminous output as a combination of the other LED chips 12-1 to 12-4 so that aggregate emission output is similar despite such selective switching. By way of example, the LED chip 12-5 may be scaled to a larger size while the LED chips 12-1 to 12-4 may be scaled smaller to provide the similar luminous outputs.

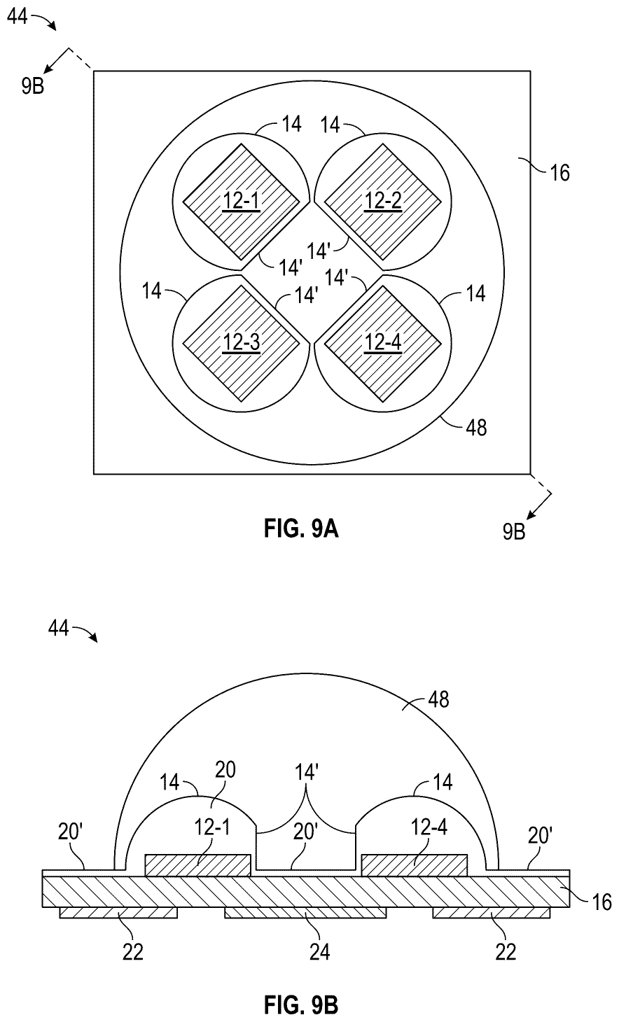

FIG. 9A is a top view of an LED package 44 similar to the LED package 38 of FIG. 6 for compound lens embodiments where another lens 48 is formed to cover each individual lens 14. FIG. 9B is a cross-sectional view of the LED package 44 of FIG. 9A taken along the cross-sectional line 9B-9B of FIG. 9A. As illustrated, the planar side surfaces 14′ may form vertical sidewalls that extend toward the submount 16 and are interconnected by the extension 20′ of the encapsulant 20. It is appreciated that such a cross-sectional view for the planar side surfaces 14′ of FIG. 9B may be the same for the planar side surfaces 14′ for FIGS. 5 and 6. While the LED package 44 is provided in the context of the arrangement of lenses 14 and LED chips 12-1 to 12-4 as described above for FIG. 6, the principles described for the lens 48 covering each smaller lens 14 are applicable to all of the previously described embodiments for FIGS. 1A to 8B. The larger lens 48 is provided to cover and extend past each individual lens 14 on the submount 16. In this manner, emissions that escape each individual lens 14 may be combined and collectively shaped by the larger lens 48 to provide a desired aggregate emission profile. In certain embodiments, the planar side surfaces 14′ of each smaller lens 14 are positioned to face each other toward the center of the submount 16, thereby increasing amounts of light that exit each lens 14 and subsequently interact with curved lateral surfaces of the larger lens 48. Alternatively, one or more of the planar side surfaces 14′ may face away from each other as illustrated in FIG. 5. In certain embodiments, perimeter edges of the lens 48 may terminate on portions of the extension 20′ of the encapsulant 20.

In certain embodiments, the lens 48 may be formed of a same material as the encapsulant 20 and the lenses 14. In other embodiments, the material of the lens 48 may deviate from the encapsulant 20 to provide further optical tailoring. For example, the lens 48 may be formed with a material having a different index of refraction than the encapsulant 20, such as an index of refraction that is intermediate the encapsulant 20 and the surrounding environment (e.g., air), thereby forming an index of refraction step for light extraction. In other embodiments, the lens 48 may be formed of a material with increased light-scattering as compared to the material of the encapsulant 20. For example, the lens 48 may be formed of a binder, such as the same material as the encapsulant 20, and may further include light-scattering particles dispersed within the binder. In still further embodiments, the lens 48 may form various shapes, such as dome-shaped, hemispheric, ellipsoid, ellipsoid bullet, cubic, flat, hex-shaped, square, shapes with curved and planar surfaces, such as a hemispheric or curved top portion with planar side surfaces. In certain embodiments, the lens 48 may be configured to provide various directional emission patterns, such as batwing distribution where luminous intensity is greater along off-axis emission angles rather than an on-axis direction.

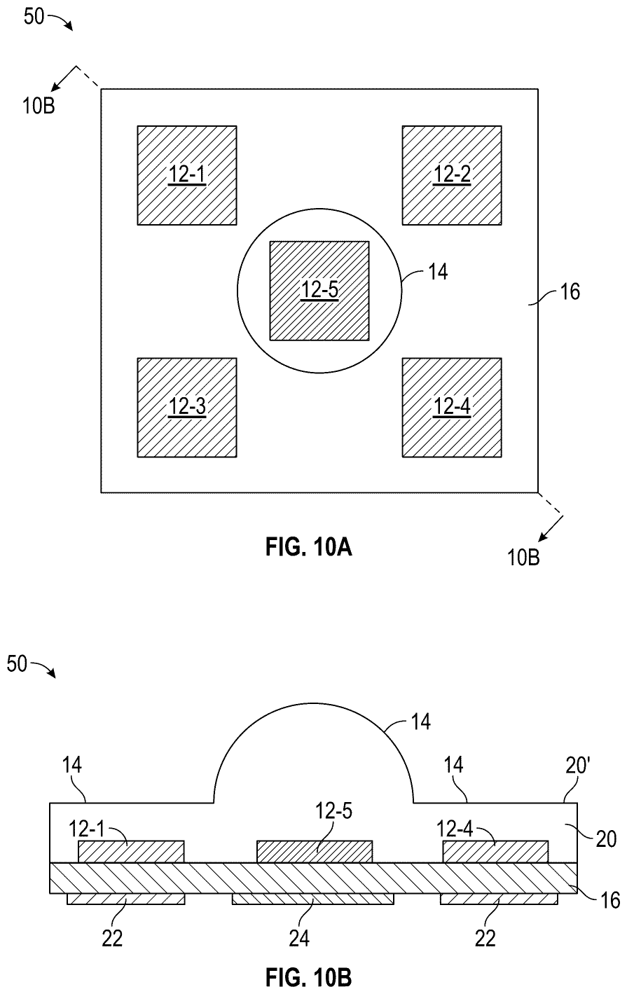

FIG. 10A is a top view of an LED package 50 similar to the LED package 10 of FIG. 1A for an alternative embodiment of the encapsulant 20. FIG. 10B is a cross-sectional view of the LED package 50 of FIG. 10A taken along the cross-sectional line 10B-10B of FIG. 10A. As best illustrated in FIG. 10B, the lateral extension 20′ of the encapsulant 20 is thick enough to cover the LED chips 12-1 to 12-4, thereby forming the corresponding lens 14 as a flat or planar lens over LED chips 12-1 to 12-4. The lens 14 over the LED chip 12-5 is formed with a curved shape, such as a dome or hemisphere, that extends above the lateral extension 20′. As with other embodiments, the flexibility in providing multiple lens shapes, such as combinations of flat and curved, by way of the common encapsulant 20, permits tailoring aggregate emission patterns in a simplified manner.

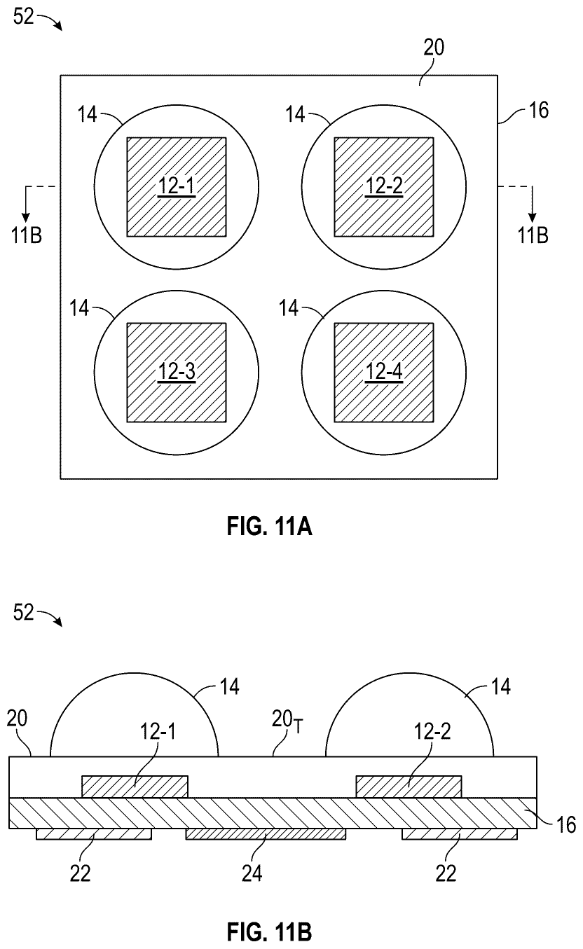

FIG. 11A is a top view of an LED package 52 similar to the LED package 10 of FIG. 1A for an alternative embodiment of the encapsulant 20 and lenses 14. FIG. 11B is a cross-sectional view of the LED package 52 of FIG. 11A taken along the cross-sectional line 11B-11B of FIG. 11A. Instead of forming the lenses 14 as integral portions of the encapsulant 20 as described above with respect to FIGS. 1A and 1B, the lenses 14 of FIGS. 11A and 11B are separate structures formed on the encapsulant 20. The separately formed lenses 14 may comprise various materials, including silicone, glass, sapphire, quartz, epoxy, and combinations thereof. In certain embodiments, the encapsulant 20 may be formed with a generally planar top surface 20_{T} that covers each LED chip 12-1 to 12-4. Individual lenses 14 may be formed on the top surface 20_{T} in positions that are vertically registered over corresponding ones of the LED chips 12-1 to 12-4. By forming the individual lenses 14 separately, the encapsulant 20 with the planar top surface 20_{T} may be formed in bulk for many LED packages, followed by tailoring of lenses 14 to target various aggregate emission patterns. Additionally, the individual lenses 14 may be readily formed with differing shapes based on targeted emission patterns.

In certain embodiments, the separately formed nature for the lenses 14 of FIGS. 11A and 11B allow for deviations in material type in similar manner as described for the lens 48 of FIGS. 9A and 9B. For example, the lenses 14 may be formed with a material having a different index of refraction than the encapsulant 20, such as an index of refraction that is intermediate the encapsulant 20 and the surrounding environment (e.g., air), thereby forming an index of refraction step for light extraction. In other embodiments, the lenses 14 may be formed of a material with increased light-scattering as compared to the material of the encapsulant 20. For example, the lenses 14 may be formed of a binder, such as the same material as the encapsulant 20, and may further include light-scattering particles and/or lumiphoric particles dispersed within the binder.

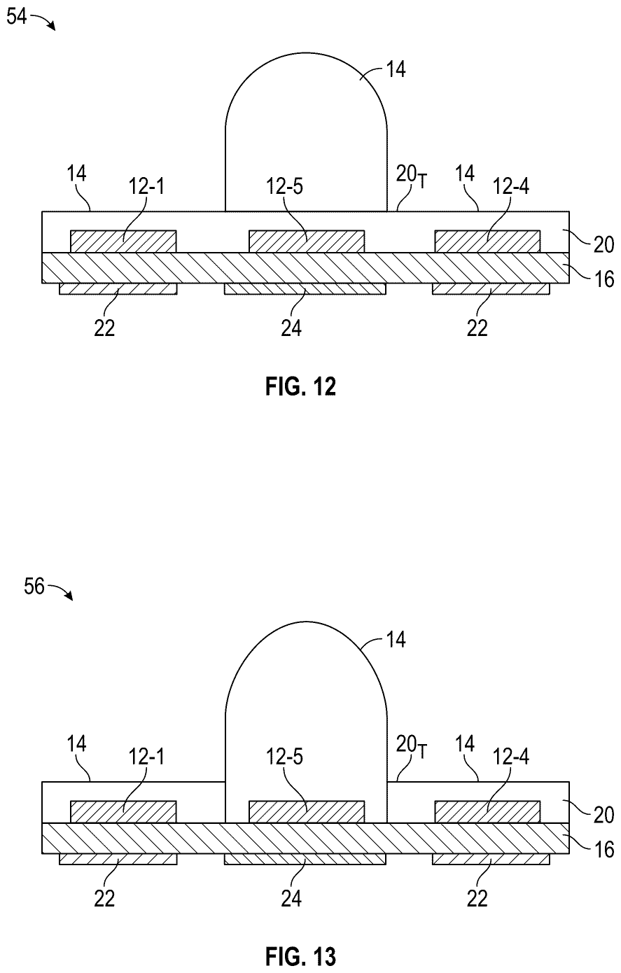

FIG. 12 is a cross-sectional view of an LED package 54 similar to the LED package 50 of FIGS. 10A and 10B for an alternative embodiment of the encapsulant 20 and lenses 14. The LED package 54 is further similar to the LED package 52 of FIGS. 11A and 11B. In FIG. 12, the lens 14 for the centrally positioned LED chip 12-5 embodies a separate structure formed on the encapsulant 20 as described above with respect to FIGS. 11A and 11B. In this arrangement, the lens 14 for the LED chip 12-5 is on the planar top surface 20_{T} of the encapsulant 20. However, the lenses 14 for the other LED chips 12-1 to 12-4 are integrally formed with the encapsulant 20 as flat lenses as described above with respect to FIGS. 10A and 10B.

FIG. 13 is a cross-sectional view of an LED package 56 similar to the LED package 54 of FIG. 12 for an alternative arrangement of the encapsulant 20 and lenses 14. In FIG. 13, the lens 14 for the LED chip 12-5 is formed before the encapsulant 20. In this regard, the lens 14 for the LED chip 12-5 is formed to cover the LED chip 12-5 and portions of the submount 16 before the encapsulant 20. As illustrated, the lens 14 for the LED chip 12-5 extends through the encapsulant 20 such that the planar top surface 20_{T} terminates or is otherwise bounded at a portion of the lens 14 that is above the first LED chip 12-5. As with FIG. 12, the lenses 14 for the other LED chips 12-1 to 12-4 are integrally formed with the encapsulant 20 as flat lenses as described above with respect to FIGS. 10A and 10B.

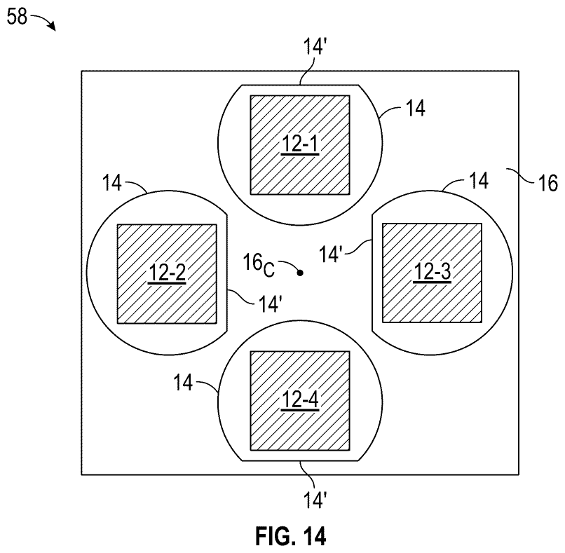

FIG. 14 is a top view of an LED package 58 similar to the LED package 36 of FIG. 5 for embodiments with an alternative layout of the lenses 14 and corresponding planar side surfaces 14′. In FIG. 14, the lenses 14 for the LED chips 12-1 and 12-4 are arranged such that their respective planar side surfaces 14′ face away from the center point 16C of the top surface of the submount 16 toward opposing perimeter edges of the submount 16.

Accordingly, emissions from each LED chip 12-1 and 12-4 may experience increased TIR near the perimeter of the submount 16 to provide narrower emission patterns. In contrast, the lenses 14 for the LED chips 12-2 and 12-3 are arranged such that their respective planar side surfaces 14′ face toward the center point 16C from the other opposing perimeter edges of the submount 16. Accordingly, emissions from each LED chip 12-2 and 12-3 may experience increased TIR near the center point 16C to provide wider emission patterns. Aggregate emissions for the LED package 58 may provide oval shaped emission patterns with increased angles of emissions in opposing directions relative to the LED chips 12-2 and 12-3 and decreased angles of emissions in opposing directions relative to the LED chips 12-1 and 12-4. Such an arrangement may be well suited for streetlight applications, among others, where oval aggregate emission patterns are needed.

In certain embodiments, any of the lenses 14 and/or the lenses 48 as described above for FIGS. 1A to 14 may form various shapes, such as dome-shaped, hemispheric, ellipsoid, ellipsoid bullet, cubic, flat, hex-shaped, square, shapes with curved and planar surfaces, such as a hemispheric or curved top portion with planar side surfaces. In certain embodiments, any of the lenses 14 and/or the lenses 48 may be configured to provide various directional emission patterns, such as batwing distribution where luminous intensity is greater along off-axis emission angles rather than an on-axis direction.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a submount;
a plurality of LED chips on the submount; and
an encapsulant on the plurality of LED chips and the submount, the encapsulant forming a plurality of lenses on the plurality of LED chips and a lateral extension integrally connecting each lens of the plurality of lenses, the lateral extension further extending to a perimeter edge of the submount.

2. The LED package of claim 1, wherein the plurality of LED chips comprises a first LED chip and a second LED chip, wherein lateral edges of the first LED chip are nonparallel with any perimeter edge of the submount, and lateral edges of the second LED chip are parallel with at least one perimeter edge of the submount.

3. The LED package of claim 1, wherein the plurality of LED chips comprises a first LED chip and a second LED chip, and wherein the plurality of lenses comprises a first lens on the first LED chip and a second lens on the second LED chip.

4. The LED package of claim 3, wherein the first LED chip comprises a lumiphoric material such that a portion of light from the first LED chip is subject to wavelength conversion, and wherein the second LED chip is devoid of lumiphoric material.

5. The LED package of claim 3, wherein the first LED chip comprises a vertical chip structure with a contact structure on a light-emitting surface of the first LED chip, and the second LED chip comprises a flip-chip structure.

6. The LED package of claim 2, wherein the plurality of lenses comprises a first lens on the first LED chip and a second lens on the second LED chip, wherein the first lens and the second lens have different shapes from one another relative to the submount.

7. The LED package of claim 3, wherein:
the first lens comprises a first curved surface with a first planar side surface; and
the second lens comprises a second curved surface with a second planar side surface.

8. The LED package of claim 7, wherein the first planar side surface and the second planar side surface are positioned away from one another relative to a center point of the submount.

9. The LED package of claim 7, wherein the first planar side surface and the second planar side surface are both positioned toward a center point of the submount.

10. The LED package of claim 7, wherein a lateral edge of the first LED chip is parallel with the first planar side surface, and a lateral edge of the second LED chip is parallel with the second planar side surface.

11. The LED package of claim 7, wherein:
the plurality of LED chips comprises a third LED chip and a fourth LED chip;
the plurality of lenses comprises a third lens on the third LED chip and a fourth lens on the fourth LED chip;
the third lens comprises a third curved surface with a third planar side surface;
the fourth lens comprises a fourth curved surface with a fourth planar side surface;
the first planar side surface and the fourth planar side surface face away from a center point of the submount; and
the second planar side surface and the third planar side surface face toward the center point of the submount.

12. The LED package of claim 3, wherein the first lens comprises a thickness that is greater than a thickness of the second lens.

13. The LED package of claim 3, wherein the first lens forms a bullet shape and the second lens forms a dome shape.

14. The LED package of claim 3, wherein the first lens comprises a curved lens and the second lens comprises a flat lens.

15. The LED package of claim 1, wherein:
the plurality of LED chips comprises a first LED chip and a second LED chip; and
the plurality of lenses comprises a first lens on the first LED chip, a second lens on the second LED chip, and a third lens on both the first lens and the second lens.

16. The LED package of claim 1, further comprising package contacts on a side of the submount opposite the plurality of LED chips.

17. A light-emitting diode (LED) package comprising:
a submount;
a first LED chip and a second LED chip of the submount;
an encapsulant forming a first lens on the first LED chip, a second lens on the second LED chip, and a lateral extension integrally connecting the first lens and the second lens; and
a third lens on the encapsulant, the third lens covering the first lens, the second lens, and portions of the lateral extension.

18. The LED package of claim 17, wherein:
the first lens comprises a first curved surface with a first planar side surface; and
the second lens comprises a second curved surface with a second planar side surface.

19. The LED package of claim 18, wherein the first planar side surface and the second planar side surface are positioned away from one another on the submount.

20. The LED package of claim 18, wherein the first planar side surface and the second planar side surface are both positioned toward each other on the submount.

21. The LED package of claim 17, wherein the third lens comprises an index of refraction that is different than the encapsulant.

22. The LED package of claim 17, wherein the third lens comprises light-scattering particles dispersed in a binder.

23. A light-emitting diode (LED) package comprising:
a submount;
a first LED chip and a second LED chip of the submount;
an encapsulant covering the first LED chip and the second LED chip, the encapsulant forming a planar top surface above the first LED chip and the second LED chip; and
a first lens with a curved surface above the planar top surface in a position that is vertically registered with the first LED chip.

24. The LED package of claim 23, further comprising a second lens on the planar top surface in a position that is vertically registered with the second LED chip.

25. The LED package of claim 23, wherein the first lens is on the planar top surface.

26. The LED package of claim 23, wherein the first lens extends through the encapsulant such that the planar top surface terminates at a portion of the first lens that is above the first LED chip.
